(19) United States
(12) Patent Application Publication
(10) Pub. No.: US 2015/0340326 A1
(43) Pub. Date: Nov. 26, 2015

(54) SHUNT OF P GATE TO N GATE BOUNDARY RESISTANCE FOR METAL GATE TECHNOLOGIES

(71) Applicant: Texas Instruments Incorporated, Dallas, TX (US)

(72) Inventors: Steve LYTLE, McKinney, TX (US); Mahalingam NANDAKUMAR, Richardson, TX (US)

(21) Appl. No.: 14/282,538

(22) Filed: May 20, 2014

(51) Int. Cl. H01L 23/62; H01L 27/092; H01L 21/8238

(52) U.S. Cl. CPC H01L 23/62; H01L 21/823821; H01L 21/823871; H01L 27/0924

(57) ABSTRACT

An integrated circuit includes a component with a metal gate NMOS transistor and a metal gate PMOS transistor in which a metal gate structure of the NMOS transistor is disposed in electrical series with, and abuts, a metal gate structure of the PMOS transistor. A gate shunt is formed over a boundary between the metal gate structure of the NMOS transistor and the metal gate structure of the PMOS transistor. The gate shunt provides a low resistance connection between the metal gate structure of the NMOS transistor and the metal gate structure of the PMOS transistor. The gate shunt is free of electrical connections to other components through interconnect elements of the integrated circuit.

### FIELD OF THE INVENTION

This invention relates to the field of integrated circuits. More particularly, this invention relates to metal gate MOS transistors in integrated circuits.

### BACKGROUND OF THE INVENTION

An integrated circuit may include metal gate n-channel metal oxide semiconductor (NMOS) transistors and metal gate p-channel metal oxide semiconductor (PMOS) transistors, and may have components such as inverters, logic gates, static random access memory (SRAM) cells in which metal gates the NMOS transistors are in electrical series with, and abutting, metal gates of the PMOS transistors. In each component, there may be high-k gate dielectric material between the gate metal of the NMOS gate and the gate metal of the PMOS gate, undesirably causing high electrical resistance between the NMOS gate and the PMOS gate. Furthermore, the NMOS gate may have a low work function layer which occupies a significant portion of the NMOS gate and the PMOS gate may have a high work function layer which likewise occupies a significant portion of the PMOS gate, so that there may be an electrical junction between the NMOS gate and the PMOS gate which also causes high electrical resistance between the NMOS gate and the PMOS gate. The high electrical resistance between the NMOS gate and the PMOS gate may undesirably cause debiasing along the gates and loss of performance of the component.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

An integrated circuit includes a component with a metal gate NMOS transistor and a metal gate PMOS transistor in which a metal gate structure of the NMOS transistor is disposed in electrical series with, and abuts, a metal gate structure of the PMOS transistor. A gate shunt is formed over a boundary between the metal gate structure of the NMOS transistor and the metal gate structure of the PMOS transistor. The gate shunt is free of electrical connections to other components through interconnect elements of the integrated circuit.

### DESCRIPTION OF THE VIEWS OF THE DRAWING

FIG. 1 is a cross section of an example integrated circuit containing a component with a metal gate NMOS transistor and a metal gate PMOS transistor connected by a gate shunt.

FIG. 2A through FIG. 2H are cross sections of the integrated circuit of FIG. 1, depicted in successive stages of fabrication.

FIG. 3A through FIG. 3E are cross sections of another example integrated circuit containing a component with a metal gate NMOS transistor and a metal gate PMOS transistor connected by a gate shunt, depicted in successive stages of fabrication.

FIG. 4 is a cross section of a further example integrated circuit containing a component with a metal gate NMOS transistor and a metal gate PMOS transistor connected by a gate shunt.

FIG. 5 is a cross section of another example integrated circuit containing a component with a metal gate NMOS transistor and a metal gate PMOS transistor connected by a gate shunt.

FIG. 6 is a cross section of an example integrated circuit containing a component with a metal gate finFET and a metal gate finFET connected by a gate shunt.

### DETAILED DESCRIPTION OF EXAMPLE EMBODIMENTS

The following co-pending patent application is related and hereby incorporated by reference: U.S. patent application Ser. No. xx/xxx,xxx entitled “CONDUCTIVE SPLINE FOR METAL GATES” (Texas Instruments docket number TI-74472, filed simultaneously with this application).

The present invention is described with reference to the attached figures. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

An integrated circuit includes a component with a metal gate NMOS transistor and a metal gate PMOS transistor in which a metal gate structure of the NMOS transistor is disposed in electrical series with, and abuts, a metal gate structure of the PMOS transistor. A gate shunt is formed over a boundary between the metal gate of the NMOS transistor and the metal gate of the PMOS transistor. The gate shunt is free of electrical connections to other components through interconnect elements of the integrated circuit. An electrical connection is made to at least one of the metal gate of the NMOS transistor and the metal gate of the PMOS transistor, separately from the gate shunt. The gate shunt may be formed concurrently with other interconnect elements or may be formed separately from other interconnect elements.

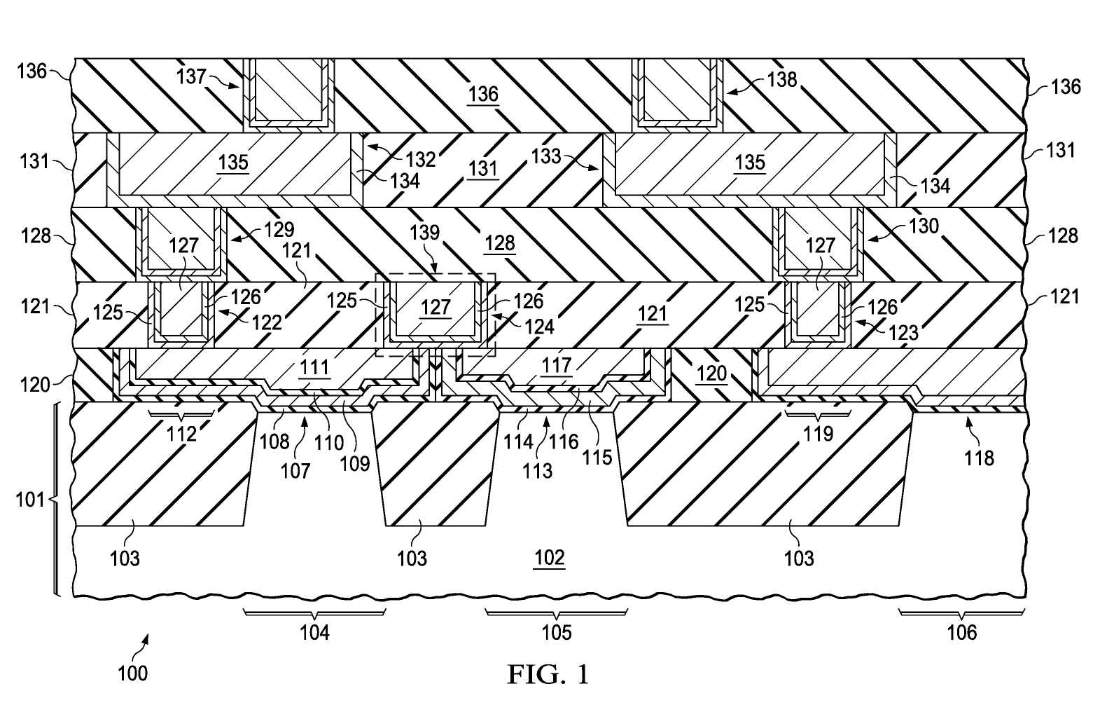

FIG. 1 is a cross section of an example integrated circuit containing a component with a metal gate NMOS transistor and a metal gate PMOS transistor connected by a gate shunt. The integrated circuit 100 is formed in and on a substrate 101 which includes semiconductor material 102. The substrate 101 may be, for example, a silicon wafer or a silicon-on-insulator (SOI) wafer. The semiconductor material 102 may be, for example, single crystal silicon of a bulk silicon wafer, or may be an epitaxially grown layer on a silicon wafer. Field oxide 103 is disposed at a top surface of the substrate 101 so as to laterally isolate an area for a metal gate NMOS transistor 104, an area for a metal gate PMOS transistor 105 and an area for a third metal gate metal oxide semiconductor (MOS) transistor 106.

The metal gate NMOS transistor 104 includes an NMOS metal gate structure 107 with a high-k gate dielectric layer 108 on the semiconductor material 102 of the substrate 101, an NMOS work function layer 109 on the gate dielectric layer 108, an NMOS barrier 110 on the NMOS work function layer 109, and an NMOS fill metal 111 on the NMOS barrier 110. The high-k gate dielectric layer 108 may be 1 nanometer to 3 nanometers thick and may include, for example, hafnium oxide, zirconium oxide and/or tantalum oxide. The NMOS work function layer 109 may be 2 nanometers to 10 nanometers thick and may include, for example, titanium, tantalum, titanium nitride, tantalum nitride, or other refractory metals. The NMOS barrier 110 may be 2 nanometers to 5 nanometers thick and may include, for example, titanium nitride, tantalum nitride, or other metallic materials which provide barriers to elements such as aluminum in the NMOS fill metal 111. The NMOS fill metal 111 may be at least 20 nanometers thick and may include, for example, aluminum and/or cobalt aluminum alloy. Other layer configurations of the NMOS metal gate structure 107 are within the scope of the instant embodiment. The NMOS metal gate structure 107 extends onto an adjacent instance of the field oxide 103 to provide a landing area 112 for a contact.

The metal gate PMOS transistor 105 includes a PMOS metal gate structure 113 with a high-k gate dielectric layer 114 on the semiconductor material 102 of the substrate 101, a PMOS work function layer 115 on the gate dielectric layer 114, a PMOS barrier 116 on the PMOS work function layer 115, and a PMOS fill metal 117 on the PMOS barrier 116. The high-k gate dielectric layer 114 may be 1 nanometer to 3 nanometers thick, may include hafnium oxide, zirconium oxide and/or tantalum oxide, and may have a similar composition to the high-k gate dielectric layer 108 of the NMOS metal gate structure 107. The PMOS work function layer 115 may be 2 nanometers to 10 nanometers thick and may include titanium, tantalum, titanium nitride, tantalum nitride, or other refractory metals, with a different composition from the NMOS work function layer 109. The PMOS barrier 116 may be 2 nanometers to 5 nanometers thick and may include, for example, titanium nitride, tantalum nitride, or other metallic materials which provide barriers to elements such as aluminum in the PMOS fill metal 117. The PMOS fill metal 117 may be at least 20 nanometers thick and may include, for example, aluminum and/or cobalt aluminum alloy, may have a similar composition to the NMOS fill metal 111. Other layer configurations of the PMOS metal gate structure 113, are within the scope of the instant embodiment. In the instant example, the PMOS metal gate structure 113 does not include a landing area for a contact.

The PMOS metal gate structure 113 is contiguous with the NMOS metal gate structure 107. In the instant example, the high-k gate dielectric layer 108 extends up onto lateral surfaces of the NMOS metal gate structure 107 and the high-k gate dielectric layer 114 extends up onto lateral surfaces of the PMOS metal gate structure 113, so that the high-k gate dielectric layer 108 and the high-k gate dielectric layer 114 are disposed between the NMOS fill metal 111 and the PMOS fill metal 117, resulting in a high electrical resistance between the NMOS fill metal 111 and the PMOS fill metal 117 through the high-k gate dielectric layer 108 and the high-k gate dielectric layer 114.

The third metal gate MOS transistor 106 includes a third metal gate structure 118 which may be similar to the NMOS metal gate structure 107 or the PMOS metal gate structure 113. In the instant example, the third metal gate MOS transistor 106 is an n-channel transistor and the third metal gate structure 118 is similar to the NMOS metal gate structure 107. The third metal gate structure 118 extends onto an adjacent instance of the field oxide 103 to provide a landing area 119 for a contact.

The integrated circuit 100 includes a lower dielectric layer 120 surrounding the NMOS metal gate structure 107, the PMOS metal gate structure 113 and the third metal gate structure 118. The lower dielectric layer 120 may include mostly silicon dioxide, possibly with a layer of silicon nitride. A top surface of the lower dielectric layer 120 may be substantially coplanar with top surfaces of the NMOS metal gate structure 107, the PMOS metal gate structure 113 and the third metal gate structure 118.

The integrated circuit 100 further includes a lower pre-metal dielectric (PMD) layer 121 disposed over the lower dielectric layer 120, the NMOS metal gate structure 107, the PMOS metal gate structure 113 and the third metal gate structure 118. The lower PMD layer 121 may be, for example, 50 nanometers to 100 nanometers thick and may include mostly silicon dioxide or low-k dielectric material and possibly include an etch stop layer and/or a cap layer. Etch stop layers may also be referred to as dielectric barriers. A first lower contact 122 is disposed in the lower PMD layer 121 and makes an electrical connection to the NMOS metal gate structure 107 in the landing area 112. A second lower contact 123 is disposed in the lower PMD layer 121 and makes an electrical connection to the third metal gate structure 118 in the landing area 119. A shunt contact 124 is disposed in the lower PMD layer 121 and overlaps with, and makes electrical connections to, the NMOS fill metal 111 and the PMOS fill metal 117. In the instant example, the first lower contact 122, the second lower contact 123 and the shunt contact 124 have similar structures, which may include an adhesion layer 125 of titanium in contact with the lower PMD layer 121, a barrier layer 126 of titanium nitride on the adhesion layer 125 and a contact fill metal 127 of tungsten on the barrier layer 126. The adhesion layer 125 may provide adhesion between the barrier layer 126 and the lower PMD layer 121 and may provide reliable electrical connections to the first lower contact 122, the second lower contact 123 and the shunt contact 124. Other layer structures for the first lower contact 122, the second lower contact 123 and the shunt contact 124 are within the scope of the instant example. In the instant example, the PMOS metal gate structure 113 is free of an electrical connection in the lower PMD layer 121 other than the shunt contact 124.

The integrated circuit 100 may further include an upper PMD layer 128 disposed over the lower PMD layer 121, the first lower contact 122, the second lower contact 123 and the shunt contact 124. The upper PMD layer 128 may be, for example, 50 nanometers to 100 nanometers of silicon dioxide or low-k dielectric material, and possibly include an etch stop layer, an adhesion layer and/or a cap layer. A first upper contact 129 and a second upper contact 130 are disposed in the upper PMD layer 128, making electrical connections to the first lower contact 122 and the second lower contact 123, respectively. The first upper contact 129 and the second upper contact 130 may possibly have a similar structure to the first lower contact 122 and the second lower contact 123.

The integrated circuit 100 may further include an intra-metal dielectric (IMD) layer 131 disposed above the upper PMD layer 128, the first upper contact 129 and the second upper contact 130. The IMD layer 131 may be, for example, 70 nanometers to 150 nanometers of silicon dioxide or low-k dielectric material, and possibly include an etch stop layer, an adhesion layer and/or a cap layer. A first interconnect 132 and a second interconnect 133 are disposed in the IMD layer 131, making electrical connections to the first upper contact 129 and the second upper contact 130, respectively. The first interconnect 132 and the second interconnect 133 may be, for example, copper damascene interconnects with a liner metal 134 of tantalum and/or tantalum nitride and a fill metal 135 of copper. The first interconnect 132 or the second interconnect 133 may possibly extend laterally over the shunt contact 124.

The integrated circuit 100 may further include an inter-level (ILD) layer 136 disposed over the IMD layer 131, the first interconnect 132 and the second interconnect 133. The ILD layer 136 may be, for example, 70 nanometers to 150 nanometers of silicon dioxide or low-k dielectric material, and possibly include an etch stop layer, an adhesion layer and/or a cap layer. A first via 137 and a second via 138 are disposed in the ILD layer 136, making electrical connections to the first interconnect 132 and the second interconnect 133, respectively. The first via 137 and the second via 138 may possibly have a similar structure to the first upper contact 129 and the second upper contact 130. Alternatively, the first via 137 and the second via 138 may possibly have a single damascene structure similar to the first interconnect 132 and the second interconnect 133. Alternatively, the first via 137 and the second via 138 may possibly be parts of overlying interconnects and have a dual damascene structure.

The shunt contact 124 provides a gate shunt 139 which advantageously provides a low resistance connection from the first lower contact 122 through the NMOS metal gate structure 107 to the PMOS metal gate structure 113. The gate shunt 139 is not electrically connected to other circuit elements of the integrated circuit 100 except the NMOS metal gate structure 107 and the PMOS metal gate structure 113. The PMOS metal gate structure 113 is not electrically contacted by other circuit elements of the integrated circuit 100 except the gate shunt 139, so that a separate landing area in the PMOS metal gate structure 113 is not needed, which may advantageously reduce a size and cost of the integrated circuit 100. In an alternate version of the instant example, the NMOS metal gate structure 107 may be free of a landing area and free of electrical contact to by other circuit elements of the integrated circuit 100 except the gate shunt 139, and the PMOS metal gate structure 113 may include a landing area and may be electrically connected to other circuit elements.

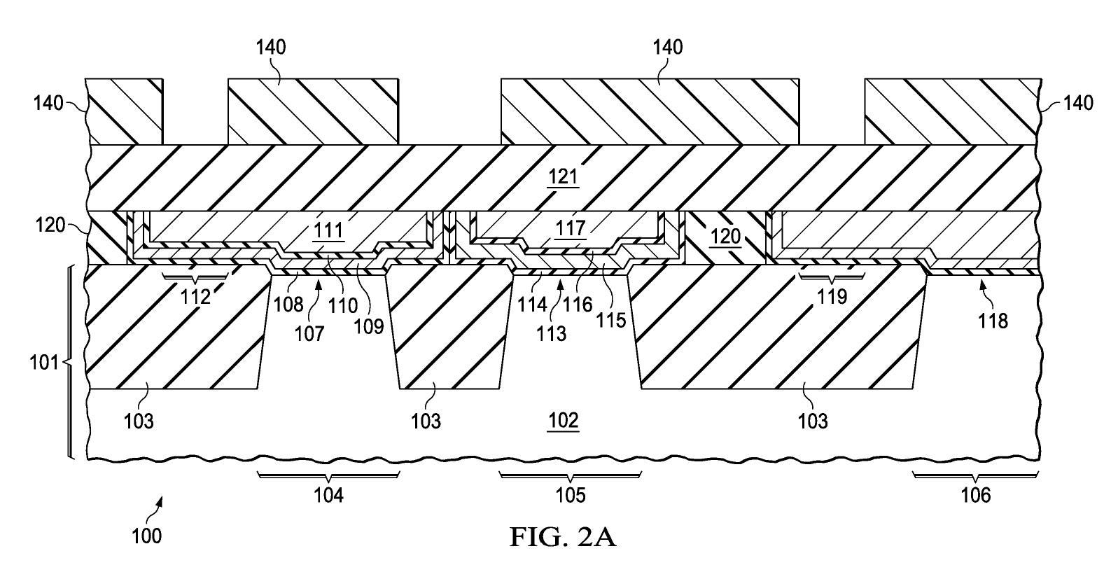

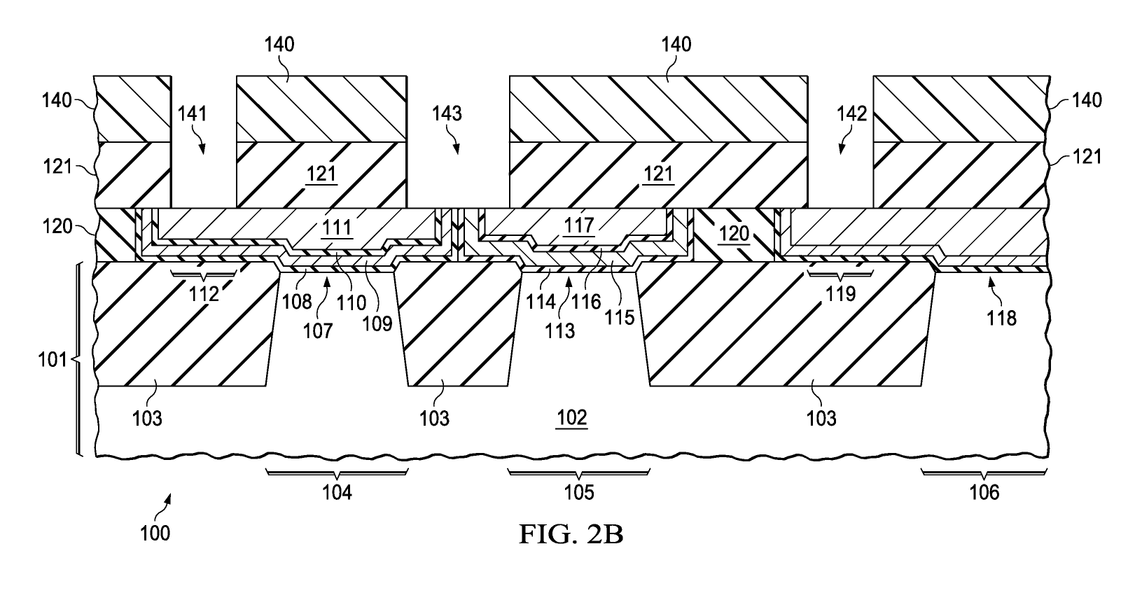

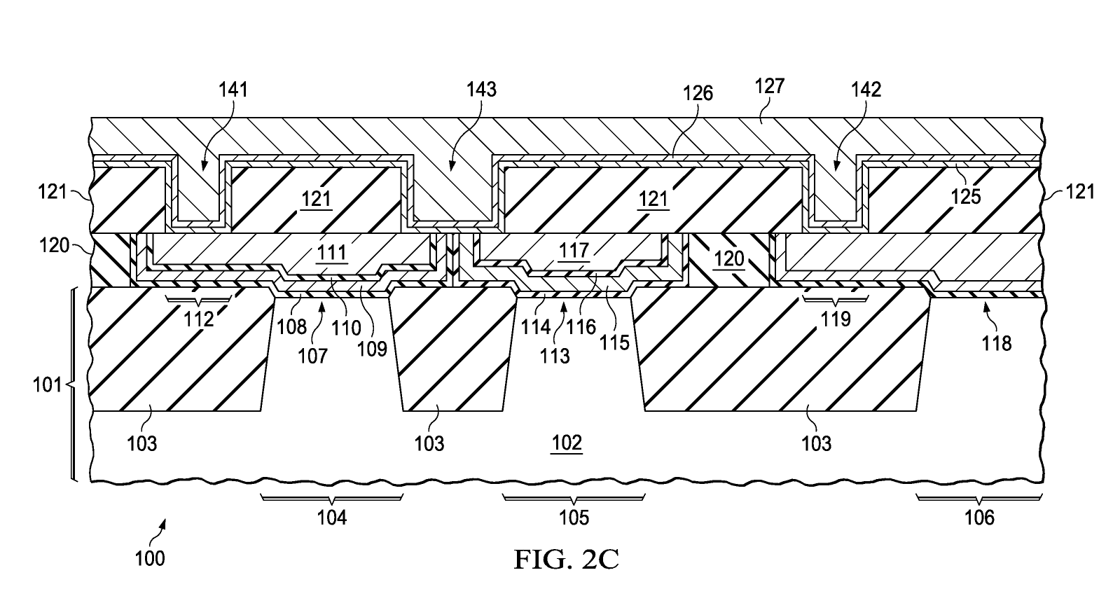

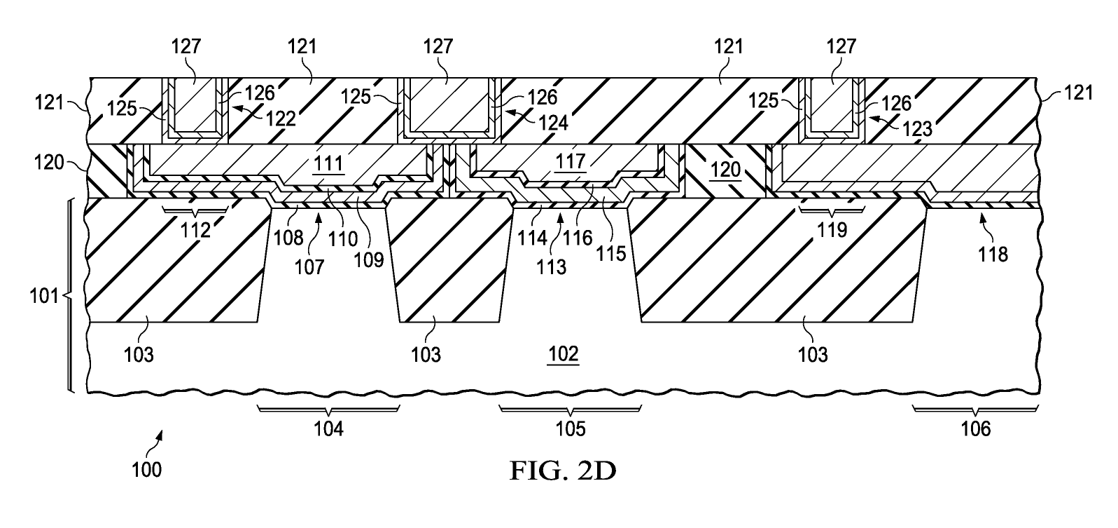

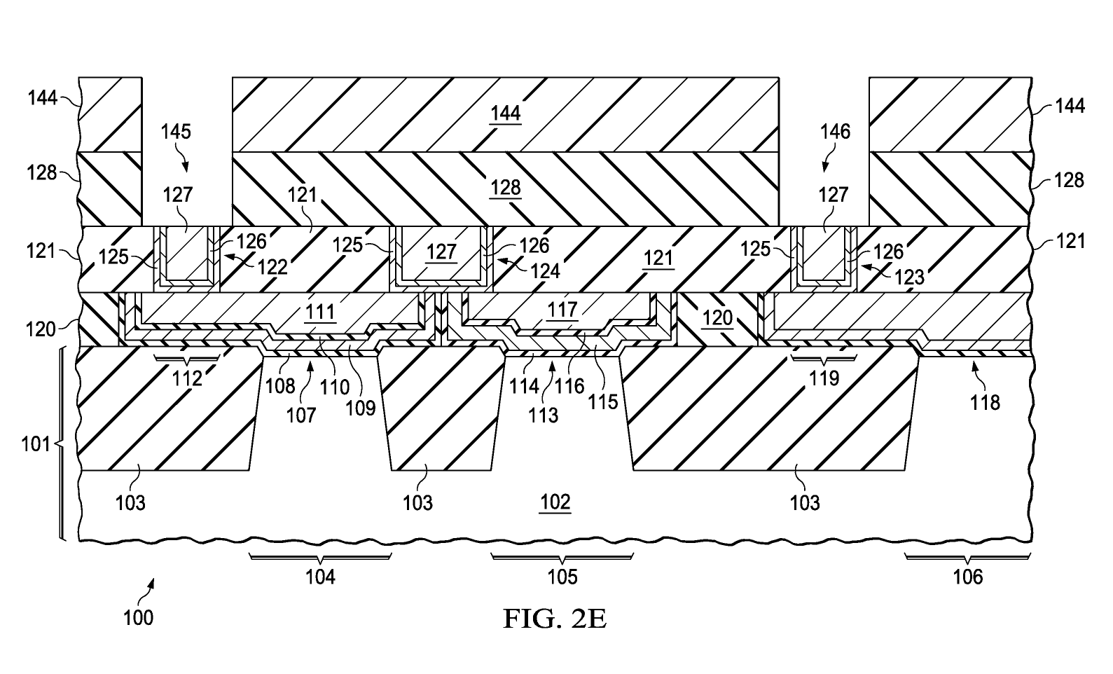

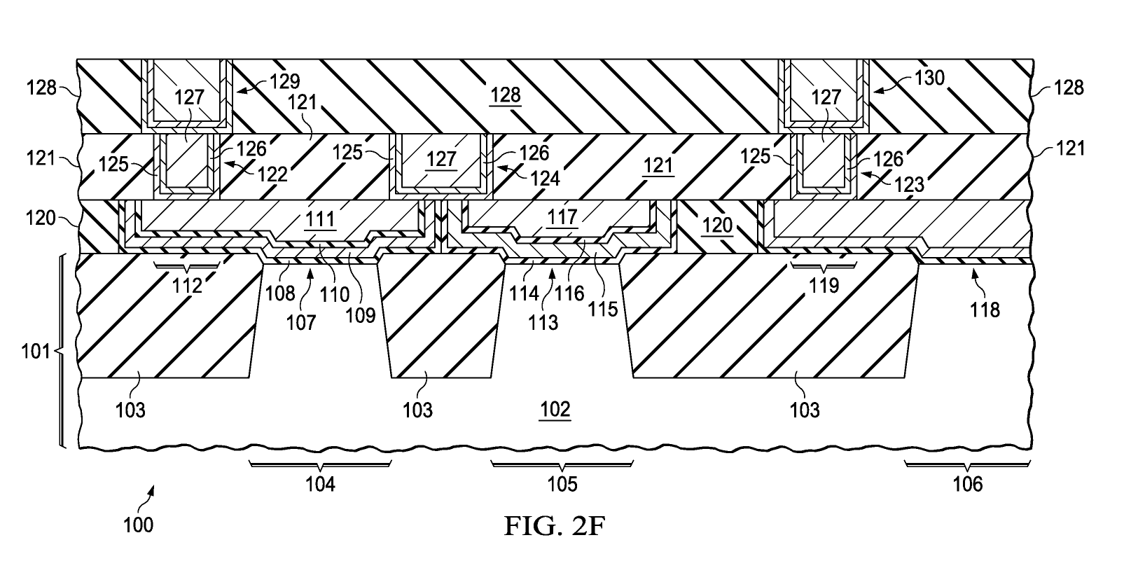

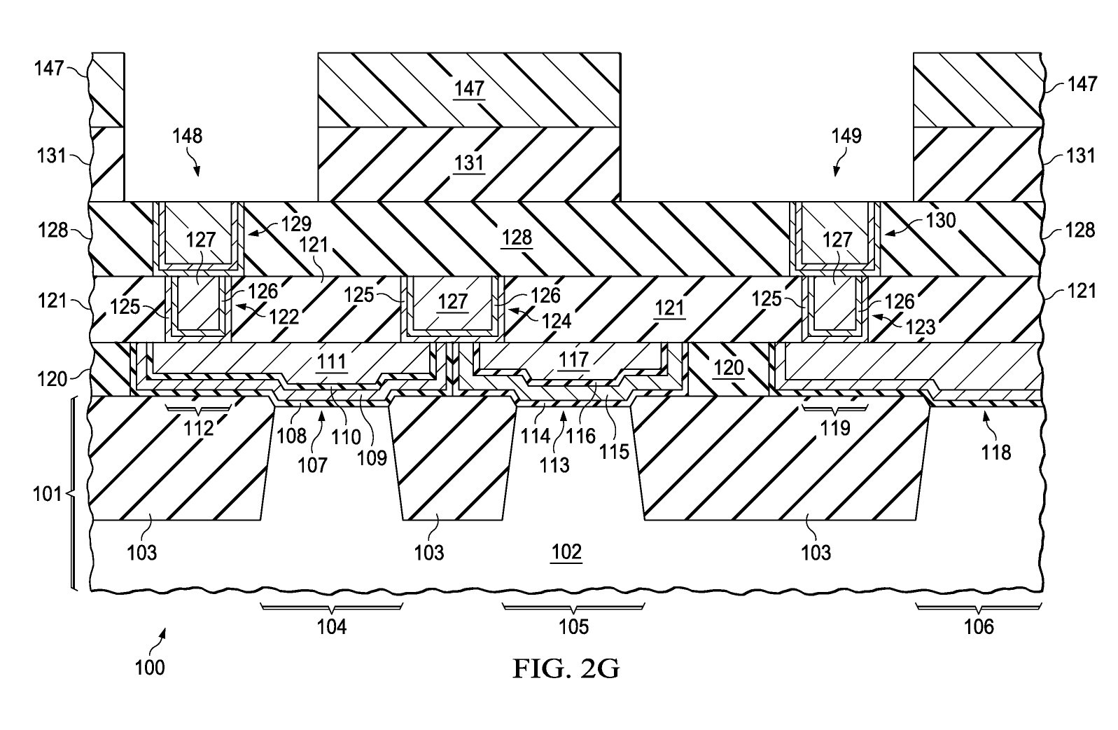

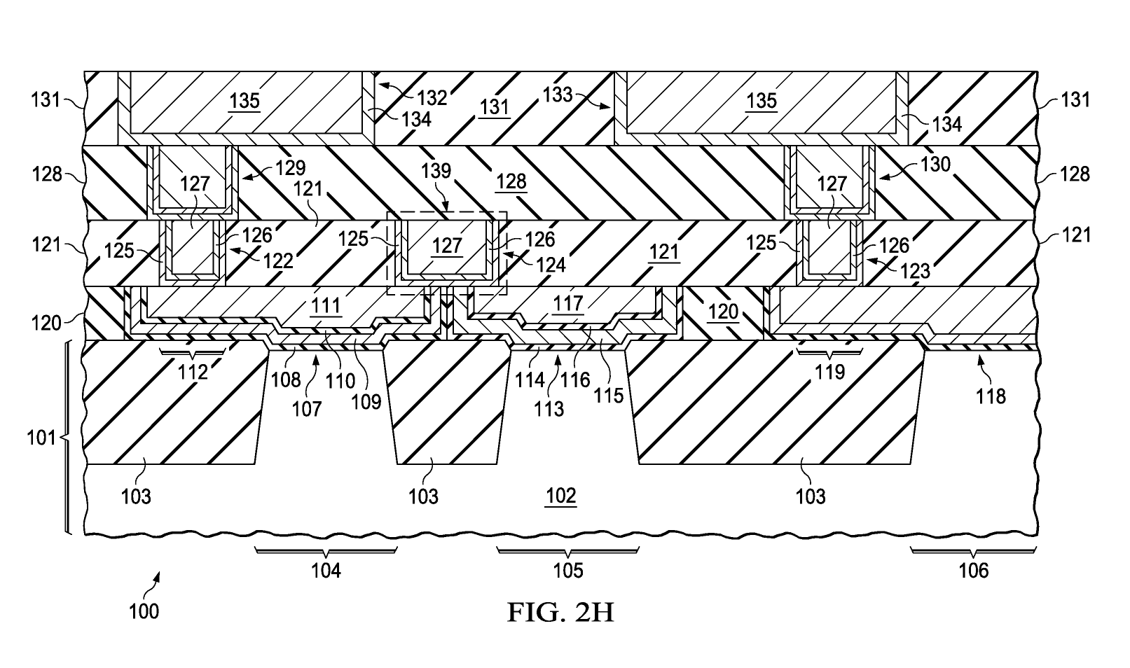

FIG. 2A through FIG. 2H are cross sections of the integrated circuit of FIG. 1, depicted in successive stages of fabrication. Referring to FIG. 2A, the integrated circuit 100 is fabricated through formation of the NMOS metal gate structure 107, the PMOS metal gate structure 113, the third metal gate structure 118, and the lower dielectric layer 120. The NMOS metal gate structure 107, the PMOS metal gate structure 113 and the third metal gate structure 118 may possibly be formed by a metal gate replacement process in which polysilicon sacrificial gates over thermal oxide gate dielectric layers are covered by the lower dielectric layer 120, which is subsequently planarized to expose top surfaces of the polysilicon sacrificial gates. Polysilicon and thermal oxide is removed from NMOS transistors and the high-k gate dielectric layer 108, the NMOS work function layer 109 and the NMOS fill metal 111 are conformally deposited. Excess high-k gate dielectric layer 108, NMOS work function layer 109 and NMOS fill metal 111 are subsequently removed from over the lower dielectric layer 120. Polysilicon and thermal oxide is removed from PMOS transistors and the high-k gate dielectric layer 114, the PMOS work function layer 115 and the PMOS fill metal 117 are conformally deposited. Excess high-k gate dielectric layer 114, PMOS work function layer 115 and PMOS fill metal 117 are subsequently removed.

The lower PMD layer 121 is formed over the lower dielectric layer 120, the NMOS metal gate structure 107, the PMOS metal gate structure 113 and the third metal gate structure 118, for example using plasma enhanced chemical vapor deposition (PECVD) processes to form an etch stop layer of silicon nitride, a main dielectric layer of boron phosphorus silicate glass (BPSG) and a cap layer of silicon carbide nitride. An etch mask 140 is formed over the lower PMD layer 121 so as to expose areas for the first lower contact 122, the second lower contact 123 and the shunt contact 124 of FIG. 1. The etch mask 140 may include photoresist over a bottom anti-reflection coating (BARC), or alternatively may include hard mask material such as amorphous carbon and silicon nitride.

Referring to FIG. 2B, dielectric material is removed from the lower PMD layer 121 in the areas exposed by the etch mask 140, to form a first hole 141 over the landing area 112 of the NMOS metal gate structure 107, a second hole 142 over the landing area 119 of the third metal gate structure 118, and a shunt hole 143 at a boundary between the NMOS metal gate structure 107 and the PMOS metal gate structure 113. The shunt hole 143 overlaps portions of the NMOS fill metal 111 and the PMOS fill metal 117. The dielectric material may be removed from the lower PMD layer 121 using a reactive ion etch (RIE) process. The etch mask 140 is subsequently removed. Photoresist and BARC may be removed by ashing. Amorphous carbon may be removed by ashing. Silicon nitride may be removed using a fluorine plasma etch process. An etch stop layer of the lower PMD layer 121 may possibly be removed from bottoms of the first hole 141, the second hole 142, and the shunt hole 143 after the etch mask 140 is removed.

Referring to FIG. 2C, the adhesion layer 125 is formed as a conformal layer on the lower PMD layer 121, extending into the first hole 141, the second hole 142 and the shunt hole 143, and making electrical contact with, the NMOS metal gate structure 107, the PMOS metal gate structure 113 and the third metal gate structure 118. The adhesion layer 125 may include, for example, 1 nanometer to 3 nanometers of titanium formed by a sputter process.

The barrier layer 126 is formed as a conformal layer on the adhesion layer 125. The barrier layer 126 may include, for example, 2 nanometers to 5 nanometers of titanium nitride formed by a reactive sputter process or an atomic layer deposition (ALD) process. The contact fill metal 127 is formed on the barrier layer 126 so as to fill the first hole 141, the second hole 142 and the shunt hole 143. The contact fill metal 127 may include 40 nanometers to 100 nanometers of tungsten formed using a metal-organic chemical vapor deposition (MOCVD) process.

Referring to FIG. 2D, the contact fill metal 127, the barrier layer 126, and the adhesion layer 125 over a top surface of the lower PMD layer 121 are removed, so as to form the first lower contact 122, the second lower contact 123 and the shunt contact 124. The contact fill metal 127, the barrier layer 126, and the adhesion layer 125 may be removed from the top surface of the lower PMD layer 121 using a chemical mechanical polish (CMP) process and/or an etchback process. Forming the shunt contact 124 concurrently with the first lower contact 122 and the second lower contact 123 may advantageously reduce fabrication cost and complexity of the integrated circuit 100.

Referring to FIG. 2E, the upper PMD layer 128 is formed over the lower PMD layer 121, the first lower contact 122, the second lower contact 123 and the shunt contact 124. The upper PMD layer 128 may be formed, for example, using PECVD processes to form an etch stop layer of silicon carbide, an adhesion layer of silicon dioxide, a main dielectric layer of organic silicon glass (OSG) and a cap layer of silicon carbide nitride. An etch mask 144 is formed over the upper PMD layer 128 so as to expose areas for the first upper contact 129 and the second upper contact 130 of FIG. 1. The etch mask 144 may include photoresist over a BARC layer, or alternatively may include hard mask material such as amorphous carbon and silicon nitride.

Dielectric material is removed from the upper PMD layer 128 in the areas exposed by the etch mask 144, to form a first hole 145 over the first lower contact 122 and a second hole 146 over the second lower contact 123. The dielectric material may be removed from the upper PMD layer 128 using an RIE process. The etch mask 144 is subsequently removed, for example as described in reference to FIG. 2B. An etch stop layer of the upper PMD layer 128 may possibly be removed from bottoms of the first hole 145 and the second hole 146 after the etch mask 144 is removed.

Referring to FIG. 2F, the first upper contact 129 and the second upper contact 130 are formed in the upper PMD layer 128 so as to make electrical connections to the first lower contact 122 and the second lower contact 123, respectively. The first upper contact 129 and the second upper contact 130 may be formed, for example, using a process sequence similar to that used in forming the first lower contact 122 and the second lower contact 123. Other processes for forming the first upper contact 129 and the second upper contact 130 are within the scope of the instant example.

Referring to FIG. 2G, the IMD layer 131 is formed over the upper PMD layer 128, the first upper contact 129 and the second upper contact 130. The IMD layer 131 may be formed, for example, using PECVD processes to form an etch stop layer of silicon carbide, a main dielectric layer of OSG and a cap layer of silicon carbide nitride. An etch mask 147 is formed over the IMD layer 131 so as to expose areas for the first interconnect 132 and the second interconnect 133 of FIG. 1. The etch mask 147 may include photoresist over a BARC layer, or alternatively may include hard mask material such as amorphous carbon and silicon nitride.

Dielectric material is removed from the IMD layer 131 in the areas exposed by the etch mask 147, to form a first trench 148 over the first upper contact 129 and a second trench 149 over the second upper contact 130. The dielectric material may be removed from the IMD layer 131 using an RIE process. The etch mask 147 is subsequently removed, for example as described in reference to FIG. 2B. An etch stop layer of the IMD layer 131 may possibly be removed from bottoms of the first trench 148 and the second trench 149 after the etch mask 147 is removed.

Referring to FIG. 2H, the first interconnect 132 and the second interconnect 133 are formed in the first trench 148 and the second trench 149 of FIG. 2G, respectively. The first interconnect 132 and the second interconnect 133 may be formed, for example, by a damascene process in which the liner metal 134 is deposited as a conformal layer over the IMD layer 131, extending into the first trench 148 and the second trench 149 and making electrical contact with the first upper contact 129 and the second upper contact 130, respectively. The liner metal 134 may include 2 nanometers to 10 nanometers of tantalum and/or tantalum nitride. A seed layer of sputtered copper is formed on the liner metal 134. Electroplated copper is formed on the seed layer to fill the first trench 148 and the second trench 149. The sputtered copper seed layer and the electroplated copper provide the fill metal 135. The fill metal 135 and the liner metal 134 are removed from over a top surface of the IMD layer 131 using a CMP process. Fabrication of the integrated circuit 100 is continued to provide the structure of FIG. 1. In the instant example, no electrical connections are formed to the gate shunt 139 in the lower PMD layer 121, the upper PMD layer 128, or dielectric layers above the upper PMD layer 128.

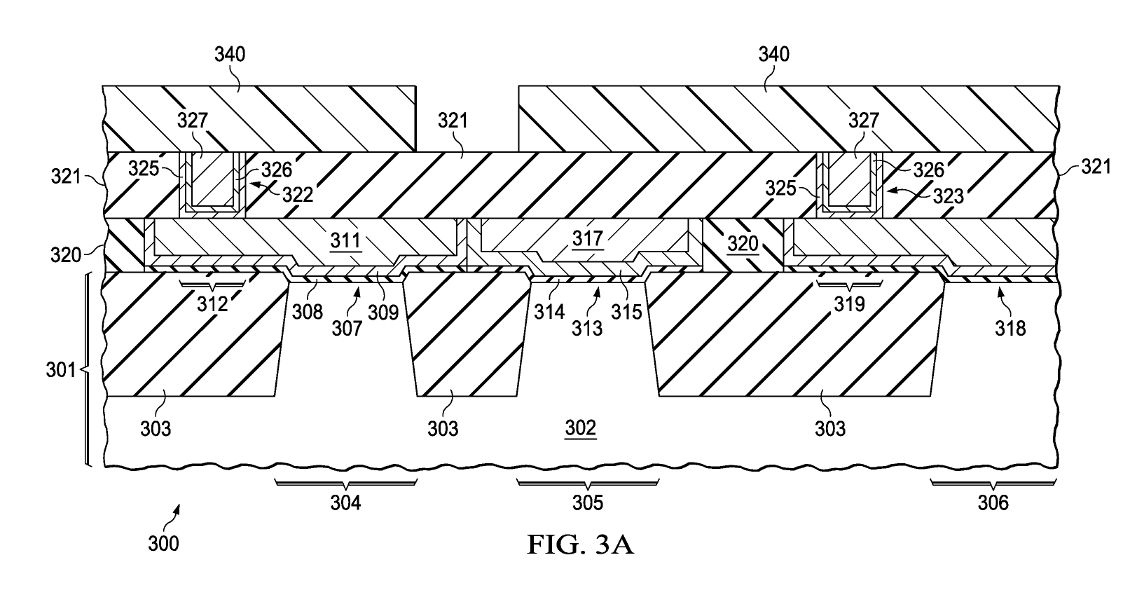

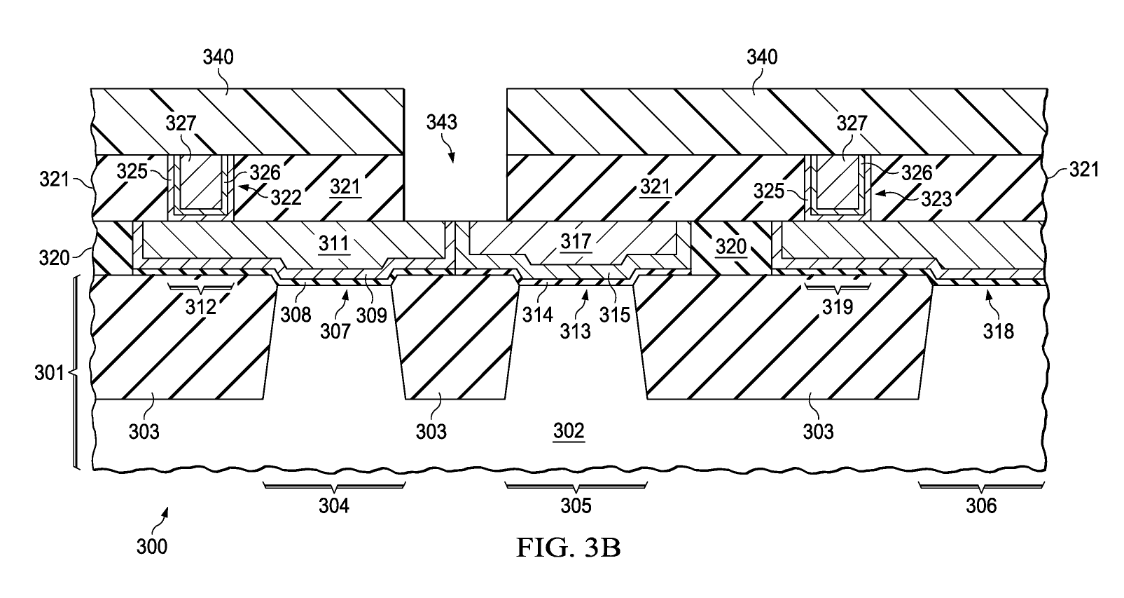

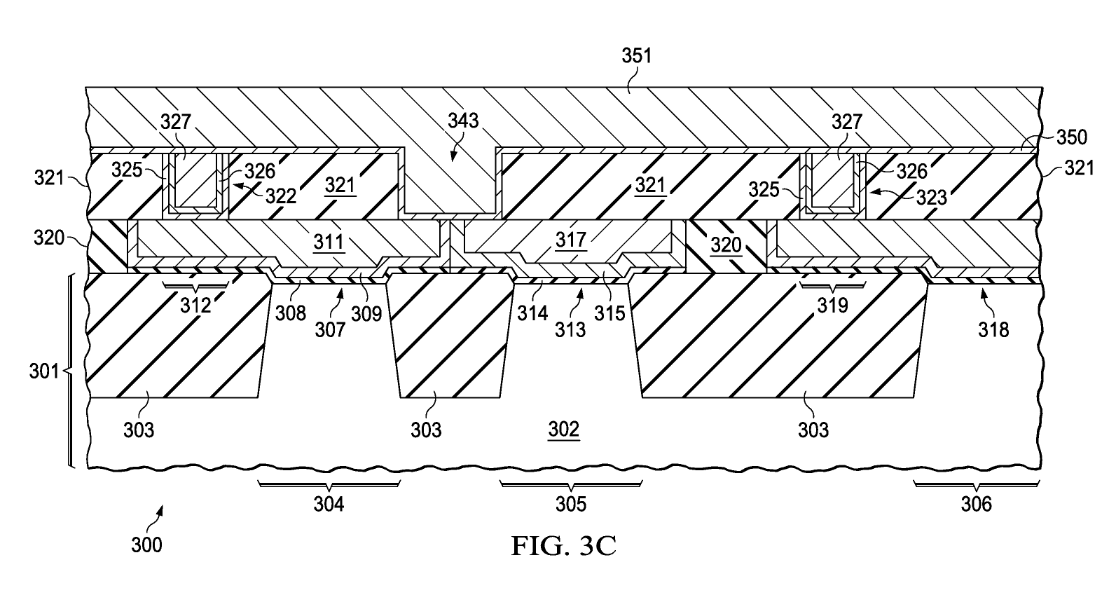

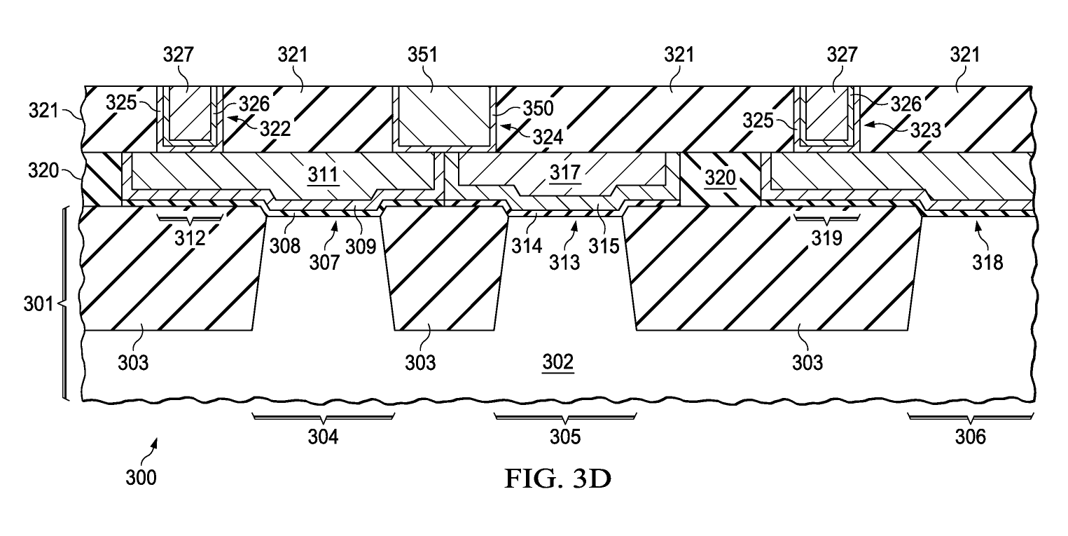

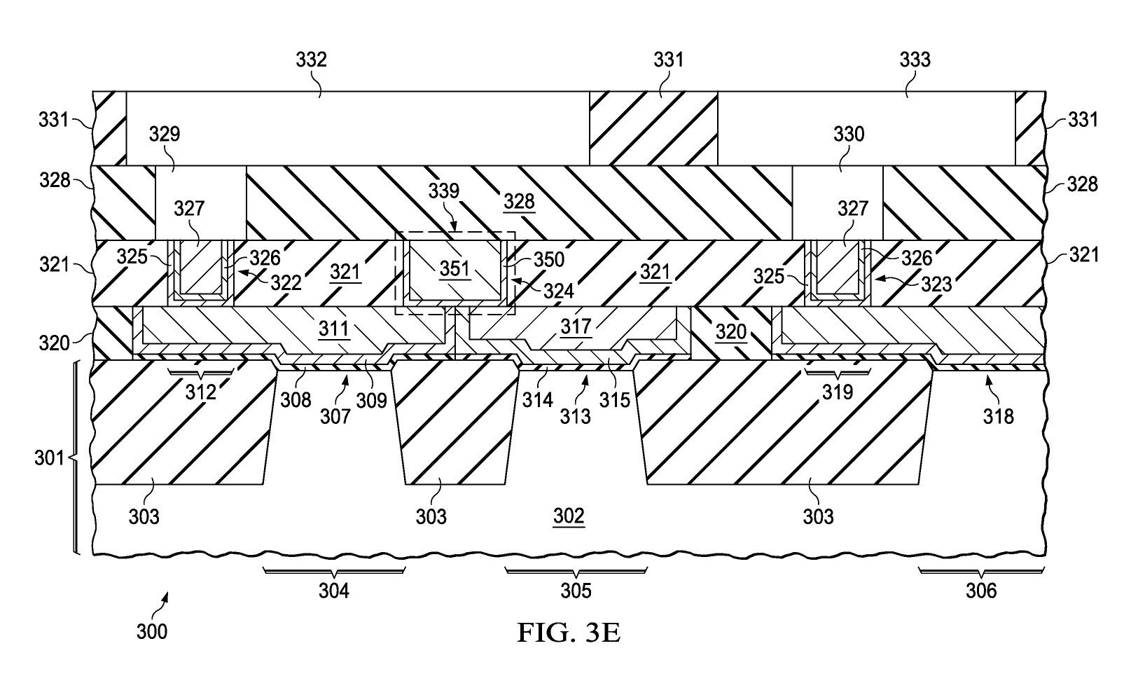

FIG. 3A through FIG. 3E are cross sections of another example integrated circuit containing a component with a metal gate NMOS transistor and a metal gate PMOS transistor connected by a gate shunt, depicted in successive stages of fabrication. Referring to FIG. 3A, the integrated circuit 300 is formed in and on a substrate 301 which includes semiconductor material 302, for example as described in reference to FIG. 1. Field oxide 303 is disposed at a top surface of the substrate 301 so as to laterally isolate an area for a metal gate NMOS transistor 304, an area for a metal gate PMOS transistor 305 and an area for a third metal gate MOS transistor 306.

The metal gate NMOS transistor 304 includes an NMOS metal gate structure 307 with a high-k gate dielectric layer 308 on the semiconductor material 302 of the substrate 301, an NMOS work function layer 309 and an NMOS fill metal 311. The high-k gate dielectric layer 308, the NMOS work function layer 309 and the NMOS fill metal 311 may have thicknesses and compositions as described in reference to FIG. 1. The NMOS metal gate structure 307 may optionally include an NMOS barrier, not shown in FIG. 3A, between the NMOS work function layer 309 and the NMOS fill metal 311. The NMOS metal gate structure 307 extends onto an adjacent instance of the field oxide 303 to provide a landing area 312 for a contact.

The metal gate PMOS transistor 305 includes a PMOS metal gate structure 313 with a high-k gate dielectric layer 314 on the semiconductor material 302 of the substrate 301, a PMOS work function layer 315 and a PMOS fill metal 317. The PMOS metal gate structure 313 may optionally include a PMOS barrier, not shown in FIG. 3A, between the PMOS work function layer 315 and the PMOS fill metal 317. The high-k gate dielectric layer 314, the PMOS work function layer 315 and the PMOS fill metal 317 may also have thicknesses and compositions as described in reference to FIG. 1. In the instant example, the PMOS metal gate structure 313 does not include a landing area for a contact.

The PMOS metal gate structure 313 is contiguous with the NMOS metal gate structure 307. In the instant example, the high-k gate dielectric layer 308 is removed on lateral surfaces of the NMOS metal gate structure 307 and the high-k gate dielectric layer 314 is removed on lateral surfaces of the PMOS metal gate structure 313, so that the NMOS fill metal 311 is separated from the PMOS fill metal 317 by the NMOS work function layer 309 and the PMOS work function layer 315. A difference in the work functions of the NMOS work function layer 309 the PMOS work function layer 315 may produce a high electrical resistance between the NMOS fill metal 311 and the PMOS fill metal 317 through the NMOS work function layer 309 and the PMOS work function layer 315.

The third metal gate MOS transistor 306 includes a third metal gate structure 318 which may be similar to the NMOS metal gate structure 307 or the PMOS metal gate structure 313. In the instant example, the third metal gate MOS transistor 306 is an n-channel transistor and the third metal gate structure 318 is similar to the NMOS metal gate structure 307. The third metal gate structure 318 extends onto an adjacent instance of the field oxide 303 to provide a landing area 319 for a contact.

The integrated circuit 300 includes a lower dielectric layer 320 surrounding the NMOS metal gate structure 307, the PMOS metal gate structure 313 and the third metal gate structure 318, as described in reference to FIG. 1. The integrated circuit 300 includes a lower PMD layer 321 disposed over the lower dielectric layer 320, the NMOS metal gate structure 307, the PMOS metal gate structure 313 and the third metal gate structure 318. The lower PMD layer 321 may have a similar structure and composition to that described in reference to FIG. 1. A first lower contact 322 is disposed in the lower PMD layer 321 and makes an electrical connection to the NMOS metal gate structure 307 in the landing area 312. A second lower contact 323 is disposed in the lower PMD layer 321 and makes an electrical connection to the third metal gate structure 318 in the landing area 319. The first lower contact 322 and the second lower contact 323 may have, for example, an adhesion layer 325 in contact with the lower PMD layer 321, a barrier layer 326 on the adhesion layer 325 and a contact fill metal 327 on the barrier layer 326.

An etch mask 340 is formed over the lower PMD layer 321 so as to expose an area for a shunt contact. The etch mask 340 may include photoresist over a BARC layer, or alternatively may include hard mask material. The area for the shunt contact is located over a boundary between the NMOS metal gate structure 307 and the PMOS metal gate structure 313, and overlaps portions of the NMOS fill metal 311 and the PMOS fill metal 317.

Referring to FIG. 3B, dielectric material is removed from the lower PMD layer 321 in the areas exposed by the etch mask 340, to form a shunt hole 343 at the boundary between the NMOS metal gate structure 307 and the PMOS metal gate structure 313. The shunt hole 343 overlaps portions of the NMOS fill metal 311 and the PMOS fill metal 317. The dielectric material may be removed from the lower PMD layer 321 using a RIE process. The etch mask 340 is subsequently removed. Photoresist and BARC may be removed by ashing. Amorphous carbon may be removed by ashing. Silicon nitride may be removed using a fluorine plasma etch process. An etch stop layer of the lower PMD layer 321 may possibly be removed from a bottom of the shunt hole 343 after the etch mask 340 is removed.

Referring to FIG. 3C, a layer of shunt adhesion layer 350 is formed as a conformal layer on the lower PMD layer 321, extending into the shunt hole 343 and making electrical contact with the NMOS fill metal 311 and the PMOS fill metal 317. The layer of shunt adhesion layer 350 may include, for example, 1 nanometer to 3 nanometers of titanium formed by a sputter process. A layer of shunt fill metal 351 is formed on the layer of shunt adhesion layer 350 so as to fill the shunt hole 343. The layer of shunt fill metal 351 may include, for example, aluminum and/or cobalt aluminum alloy, formed by a sputter process.

Referring to FIG. 3D, the shunt fill metal 351 and the shunt adhesion layer 350 are over a top surface of the lower PMD layer 321 are removed, so as to form a shunt contact 324. The shunt fill metal 351 and the shunt adhesion layer 350 may be removed, for example, using a CMP process. The shunt adhesion layer 350 may advantageously provide adhesion between the shunt fill metal 351 and the lower PMD layer 321, and may form reliable electrical connections to the NMOS fill metal 311 and the PMOS fill metal 317. Forming the shunt contact 324 with a thin adhesion layer 350 and a low resistance fill metal 351 may advantageously reduce a lateral resistance of the shunt contact 324, and hence lower resistance between the NMOS fill metal 311 and the PMOS fill metal 317, compared to a shunt contact formed concurrently with the first lower contact 322 and the second lower contact 323, because the first lower contact 322 and the second lower contact 323 may be optimized to provide a lower vertical resistance rather than a lower lateral resistance.

Referring to FIG. 3E, an upper PMD layer 328 is formed over the lower PMD layer 321, the first lower contact 322, the second lower contact 323 and the shunt contact 324, for example as described in reference to FIG. 2E. A first upper contact 329 and a second upper contact 330 are formed in the upper PMD layer 328 so as to make electrical connections to the first lower contact 322 and the second lower contact 323, respectively. The first upper contact 329 and the second upper contact 330 may be formed, for example, as described in reference to the first lower contact 122 and the second lower contact 123 of FIG. 2A through FIG. 2D.

An IMD layer 331 is formed over the upper PMD layer 328, the first upper contact 329 and the second upper contact 330. The IMD layer 331 may have a similar structure and composition, and be formed by a similar process, as described in reference to FIG. 2G. A first interconnect 332 and a second interconnect 333 are formed in the IMD layer 331 so as to make electrical connections with the first upper contact 329 and the second upper contact 330, respectively. The first interconnect 332 and the second interconnect 333 may be copper damascene interconnects, formed as described in reference to FIG. 2G and FIG. 2H.

The shunt contact 324 provides a gate shunt 339 which advantageously forms a low resistance shunt between the NMOS fill metal 311 and the PMOS fill metal 317. Either of the first interconnect 332 and the second interconnect 333 may possibly overlap the gate shunt 339 without making an electrical connection to the gate shunt 339, as depicted in FIG. 3E, which may advantageously enable a more efficient layout for the integrated circuit 300.

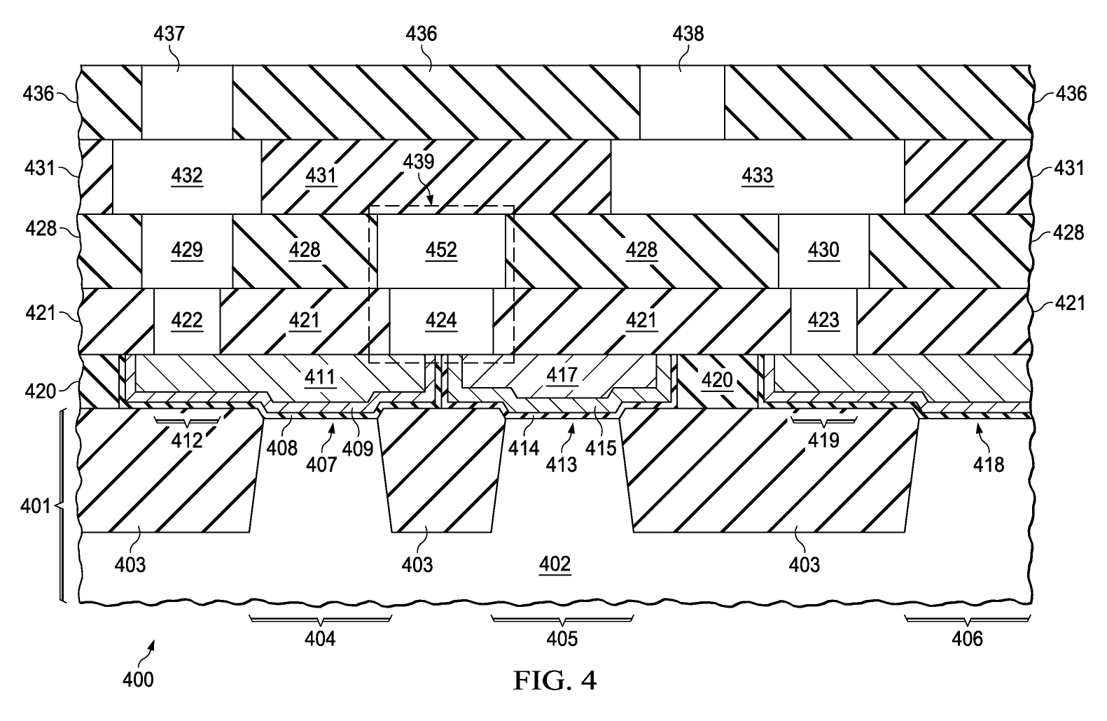

FIG. 4 is a cross section of a further example integrated circuit containing a component with a metal gate NMOS transistor and a metal gate PMOS transistor connected by a gate shunt. The integrated circuit 400 is formed in and on a substrate 401 which includes semiconductor material 402, for example as described in reference to FIG. 1. Field oxide 403 is disposed at a top surface of the substrate 401 so as to laterally isolate an area for a metal gate NMOS transistor 404, an area for a metal gate PMOS transistor 405 and an area for a third metal gate MOS transistor 406.

The metal gate NMOS transistor 404 includes an NMOS metal gate structure 407 with a high-k gate dielectric layer 408 on the semiconductor material 402, an NMOS work function layer 409 and an NMOS fill metal 411, possibly as described in reference to FIG. 1. The NMOS metal gate structure 407 may optionally include an NMOS barrier, not shown in FIG. 4, between the NMOS work function layer 409 and the NMOS fill metal 411. The NMOS metal gate structure 407 includes a landing area 412 for a contact. The metal gate PMOS transistor 405 includes a PMOS metal gate structure 413 with a high-k gate dielectric layer 414 on the semiconductor material 402, a PMOS work function layer 415 and a PMOS fill metal 417, possibly as described in reference to FIG. 1. The PMOS metal gate structure 413 may optionally include a PMOS barrier, not shown in FIG. 4, between the PMOS work function layer 415 and the PMOS fill metal 417.

The third metal gate MOS transistor 406 includes a third metal gate structure 418 which may be similar to the NMOS metal gate structure 407 or the PMOS metal gate structure 413. The third metal gate structure 418 extends onto an adjacent instance of the field oxide 403 to provide a landing area 419 for a contact.

The integrated circuit 400 includes a dielectric layer stack with a lower dielectric layer 420, a lower PMD layer 421, an upper PMD layer 428, an IMD layer 431 and an ILD layer 436, possibly as described in reference to FIG. 1. The NMOS metal gate structure 407 is electrically connected to a first interconnect stack at the landing area 412; the first interconnect stack includes a first lower contact 422, a first upper contact 429, a first interconnect 432 and a first via 437. The third metal gate structure 418 is electrically connected to a second interconnect stack at the landing area 419; the second interconnect stack includes a second lower contact 423, a second upper contact 430, a second interconnect 433 and a second via 438.

A gate shunt 439 is disposed in the dielectric stack so as to provide a low resistance shunt between the NMOS fill metal 411 and the PMOS fill metal 417. The gate shunt 439 includes a lower shunt contact 424 disposed in the lower PMD layer 421 and which makes direct electrical contact with the NMOS fill metal 411 and the PMOS fill metal 417. The lower shunt contact 424 may have a similar structure to the first lower contact 422 and the second lower contact 423, or may alternately have a different structure which has a lower lateral resistance. The gate shunt 439 further includes an upper shunt contact 452 disposed in the upper PMD layer 428 which makes electrical contact with the lower shunt contact 424. The upper shunt contact 452 may have a similar structure to the first upper contact 429 and the second upper contact 430, or may alternately have a different structure which has a lower lateral resistance. The gate shunt 439 is free of electrical connections to other interconnect elements of the integrated circuit 400. Including the upper shunt contact 452 in the gate shunt 439 may advantageously reduce an resistance between the NMOS fill metal 411 and the PMOS fill metal 417.

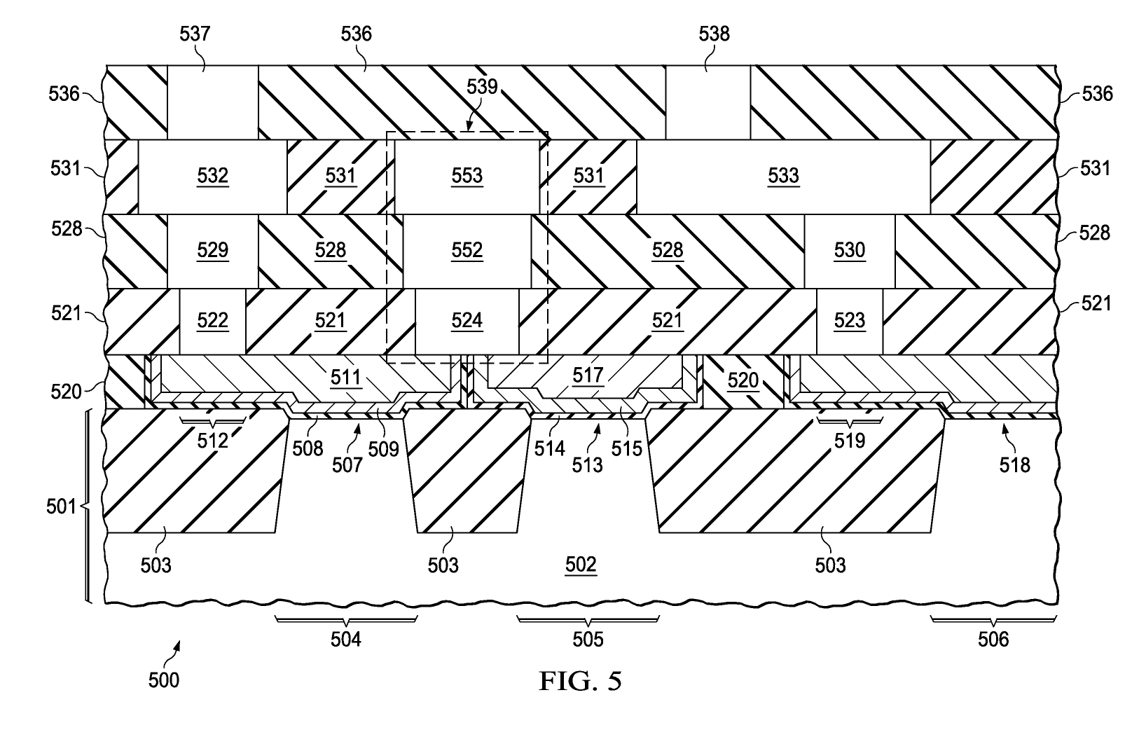

FIG. 5 is a cross section of another example integrated circuit containing a component with a metal gate NMOS transistor and a metal gate PMOS transistor connected by a gate shunt. The integrated circuit 500 is formed in and on a substrate 501 which includes semiconductor material 502, for example as described in reference to FIG. 1. Field oxide 503 is disposed at a top surface of the substrate 501 so as to laterally isolate an area for a metal gate NMOS transistor 504, an area for a metal gate PMOS transistor 505 and an area for a third metal gate MOS transistor 506.

The metal gate NMOS transistor 504 includes an NMOS metal gate structure 507 with a high-k gate dielectric layer 508 on the semiconductor material 502, an NMOS work function layer 509 and an NMOS fill metal 511, possibly as described in reference to FIG. 1. The NMOS metal gate structure 507 may optionally include an NMOS barrier, not shown in FIG. 5, between the NMOS work function layer 509 and the NMOS fill metal 511. The NMOS metal gate structure 507 includes a landing area 512 for a contact. The metal gate PMOS transistor 505 includes a PMOS metal gate structure 513 with a high-k gate dielectric layer 514 on the semiconductor material 502, a PMOS work function layer 515 and a PMOS fill metal 517, possibly as described in reference to FIG. 1. The PMOS metal gate structure 513 may optionally include a PMOS barrier, not shown in FIG. 5, between the PMOS work function layer 515 and the PMOS fill metal 517. The third metal gate MOS transistor 506 includes a third metal gate structure 518 which may be similar to the NMOS metal gate structure 507 or the PMOS metal gate structure 513. The third metal gate structure 518 extends onto an adjacent instance of the field oxide 503 to provide a landing area 519 for a contact.

The integrated circuit 500 includes a dielectric layer stack with a lower dielectric layer 520, a lower PMD layer 521, an upper PMD layer 528, an IMD layer 531 and an ILD layer 536, similar to that described in reference to FIG. 4. The NMOS metal gate structure 507 is electrically connected to a first interconnect stack at the landing area 512; the first interconnect stack includes a first lower contact 522, a first upper contact 529, a first interconnect 532 and a first via 537. The third metal gate structure 518 is electrically connected to a second interconnect stack at the landing area 519; the second interconnect stack includes a second lower contact 523, a second upper contact 530, a second interconnect 533 and a second via 538.

A gate shunt 539 is disposed in the dielectric stack so as to provide a low resistance shunt between the NMOS fill metal 511 and the PMOS fill metal 517. The gate shunt 539 includes a lower shunt contact 524 disposed in the lower PMD layer 521 and which makes direct electrical contact with the NMOS fill metal 511 and the PMOS fill metal 517. The gate shunt 539 also includes an upper shunt contact 552 disposed in the upper PMD layer 528 which makes electrical contact with the lower shunt contact 524. The gate shunt 539 further includes an upper interconnect shunt 553 disposed in the IMD layer 531 which makes electrical contact with the upper shunt contact 552. The gate shunt 539 is free of electrical connections to other interconnect elements of the integrated circuit 500. Including the upper interconnect shunt 553 in the gate shunt 539 may advantageously reduce an resistance between the NMOS fill metal 511 and the PMOS fill metal 517.

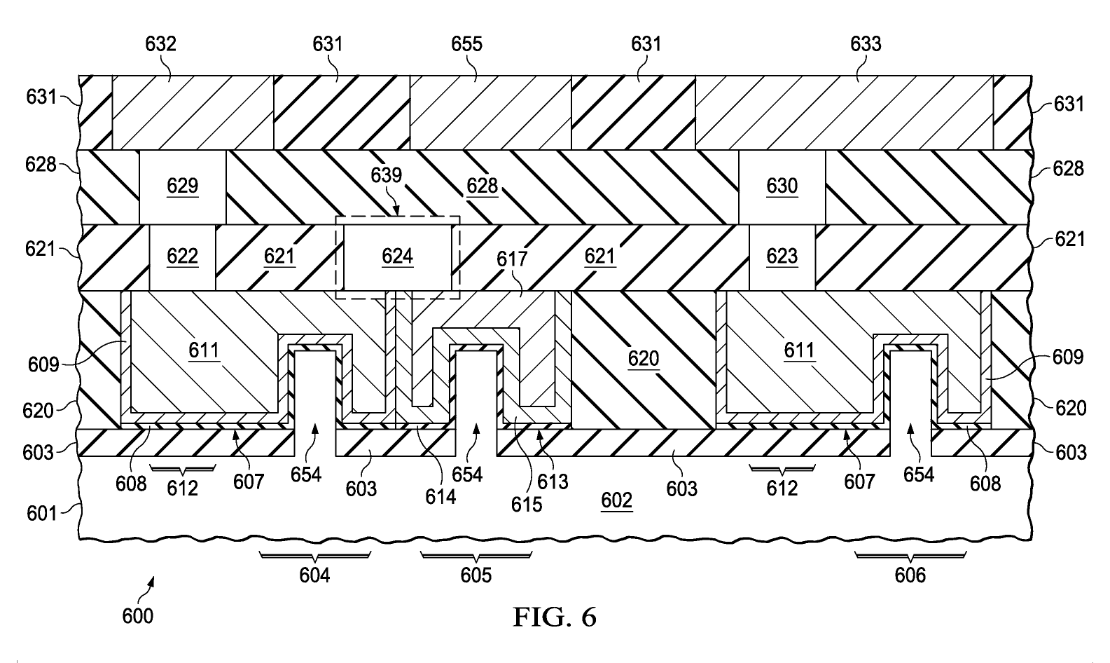

FIG. 6 is a cross section of an example integrated circuit containing a component with a metal gate fin field effect transistor (finFET) and a metal gate finFET connected by a gate shunt. The integrated circuit 600 is formed on a substrate 601 which includes semiconductor material 602 and fins 654 of the semiconductor material 602. A layer of isolation oxide 603 may be disposed on the substrate 601 surrounding the fins 654. The integrated circuit 600 includes a metal gate n-channel finFET 604, a metal gate p-channel finFET 605 and a third metal gate finFET 606.

The metal gate n-channel finFET 604 includes an NMOS metal gate structure 607 with a high-k gate dielectric layer 608 on the semiconductor material 602 of one of the fins 654, an NMOS work function layer 609 and an NMOS fill metal 611. The NMOS metal gate structure 607 may optionally include an NMOS barrier, not shown in FIG. 6, between the NMOS work function layer 609 and the NMOS fill metal 611. The high-k gate dielectric layer 608, the NMOS work function layer 609 and the NMOS fill metal 611 may have similar thicknesses and compositions to those described in reference to FIG. 1. The NMOS metal gate structure 607 extends onto an adjacent instance of the isolation oxide 603 to provide a landing area 612 for a contact.

The metal gate p-channel finFET 605 includes a PMOS metal gate structure 613 with a high-k gate dielectric layer 614 on the semiconductor material 602 of another of the fins 654, a PMOS work function layer 615 and a PMOS fill metal 617. The PMOS metal gate structure 613 may optionally include a PMOS barrier, not shown in FIG. 6, between the PMOS work function layer 615 and the PMOS fill metal 617. The high-k gate dielectric layer 614, the PMOS work function layer 615 and the PMOS fill metal 617 may have similar thicknesses and compositions to those described in reference to FIG. 1. In the instant example, the PMOS metal gate structure 613 does not include a landing area for a contact.

The PMOS metal gate structure 613 is contiguous with the NMOS metal gate structure 607. In the instant example, the high-k gate dielectric layer 608 may be removed on lateral surfaces of the NMOS metal gate structure 607 and the high-k gate dielectric layer 614 is removed on lateral surfaces of the PMOS metal gate structure 613, so that the NMOS fill metal 611 is separated from the PMOS fill metal 617 by the NMOS work function layer 609 and the PMOS work function layer 615. A difference in the work functions of the NMOS work function layer 609 the PMOS work function layer 615 may provide a high electrical resistance between the NMOS fill metal 611 and the PMOS fill metal 617 through the NMOS work function layer 609 and the PMOS work function layer 615. Alternately, the high-k gate dielectric layer 608 may extend up onto lateral surfaces of the NMOS metal gate structure 607 and the high-k gate dielectric layer 614 extends up onto lateral surfaces of the PMOS metal gate structure 613, so that the NMOS fill metal 611 is separated from the PMOS fill metal 617 by the high-k gate dielectric layer 608 and the high-k gate dielectric layer 614, resulting in a high resistance between the NMOS fill metal 611 and the PMOS fill metal 617 through the high-k gate dielectric layer 608 and the high-k gate dielectric layer 614.

The third metal gate finFET 606 includes a third metal gate structure 618 which may be similar to the NMOS metal gate structure 607 or the PMOS metal gate structure 613. In the instant example, the third metal gate finFET 606 is an n-channel transistor and the third metal gate structure 618 is similar to the NMOS metal gate structure 607. The third metal gate structure 618 extends onto an adjacent instance of the isolation oxide 603 to provide a landing area 619 for a contact.

The integrated circuit 600 includes a lower dielectric layer 620 surrounding the NMOS metal gate structure 607, the PMOS metal gate structure 613 and the third metal gate structure 618. The lower dielectric layer 620 may include mostly silicon dioxide, possibly with a layer of silicon nitride. A top surface of the lower dielectric layer 620 may be substantially coplanar with top surfaces of the NMOS metal gate structure 607, the PMOS metal gate structure 613 and the third metal gate structure 618. The integrated circuit 600 includes a dielectric layer stack over the lower dielectric layer 620 and the NMOS metal gate structure 607, the PMOS metal gate structure 613 and the third metal gate structure 618. The dielectric layer stack includes a lower PMD layer 621, an upper PMD layer 628 and an IMD layer 631, possibly as described in reference to FIG. 1. The NMOS metal gate structure 607 is electrically connected to a first interconnect stack at the landing area 612; the first interconnect stack includes a first lower contact 622, a first upper contact 629, a first interconnect 632. The third metal gate structure 618 is electrically connected to a second interconnect stack at the landing area 619; the second interconnect stack includes a second lower contact 623, a second upper contact 630, a second interconnect 633.

A gate shunt 639 is disposed in the dielectric stack so as to provide a low resistance shunt between the NMOS fill metal 611 and the PMOS fill metal 617. The gate shunt 639 includes a lower shunt contact 624 disposed in the lower PMD layer 621 and which makes direct electrical contact with the NMOS fill metal 611 and the PMOS fill metal 617. The lower shunt contact 624 may have a similar structure to the first lower contact 622 and the second lower contact 623, or may alternately have a different structure which has a lower lateral resistance. The gate shunt 639 is free of electrical connections to other interconnect elements of the integrated circuit 600. Including the upper shunt contact 652 in the gate shunt 639 may advantageously reduce an resistance between the NMOS fill metal 611 and the PMOS fill metal 617. It will be recognized that the gate shunt 639 may include additional elements as described in reference to FIG. 4 and FIG. 5. A third interconnect 655 may be disposed in the IMD layer 631 over the gate shunt 639. The integrated circuit 600 may accrue the advantages discussed in reference to the other example integrated circuits described herein.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. An integrated circuit, comprising:
a substrate comprising semiconductor material;
a metal gate n-channel metal oxide semiconductor (NMOS) transistor comprising an NMOS metal gate structure;
a metal gate p-channel metal oxide semiconductor (PMOS) transistor comprising a PMOS metal gate structure, the PMOS metal gate structure abutting the NMOS metal gate structure; and
a gate shunt disposed above a boundary between the NMOS metal gate structure and the PMOS metal gate structure, the gate shunt making electrical contact with the NMOS metal gate structure and the PMOS metal gate structure and providing a low resistance connection from the NMOS metal gate structure to the PMOS metal gate structure, the gate shunt being free of an electrical connection to other components through interconnect elements in the integrated circuit.

2. The integrated circuit of claim 1, in which exactly one of the NMOS metal gate structure and the PMOS metal gate structure includes a landing area; and
the integrated circuit further comprises an electrical connection at the landing area to other circuit elements of the integrated circuit.

3. The integrated circuit of claim 1, further comprising:
a third metal gate metal oxide semiconductor (MOS) transistor comprising a third metal gate structure, the third metal gate structure including a landing area; and
a contact disposed above the third metal gate structure at the landing area, the contact making an electrical connection to the third metal gate structure, such that the contact and the gate shunt have a similar structure;

4. The integrated circuit of claim 1, in which the gate shunt includes an adhesion layer and fill metal disposed over the adhesion layer

5. The integrated circuit of claim 4, in which the adhesion layer includes titanium.

6. The integrated circuit of claim 4, in which the fill metal includes a metal selected from the group consisting tungsten, aluminum and cobalt aluminum alloy.

7. The integrated circuit of claim 1, in which the gate shunt includes a lower shunt via disposed in a lower pre-metal dielectric (PMD) layer and an upper shunt via disposed in an upper PMD layer.

8. The integrated circuit of claim 1, in which the metal gate NMOS transistor is a metal gate n-channel fin field effect transistor (finFET) and the metal gate PMOS transistor is a metal gate p-channel finFET.

9. The integrated circuit of claim 1, in which:
the NMOS metal gate structure includes an NMOS work function layer and an NMOS fill metal;
the PMOS metal gate structure includes a PMOS work function layer and a PMOS fill metal; and
the gate shunt makes electrical contact to the NMOS fill metal and the PMOS fill metal.

10. The integrated circuit of claim 1, in which:
the NMOS metal gate structure includes an NMOS work function layer, an NMOS barrier disposed on the NMOS work function layer, and an NMOS fill metal disposed on the NMOS barrier;
the PMOS metal gate structure includes a PMOS work function layer, a PMOS barrier disposed on the PMOS work function layer, and a PMOS fill metal disposed on the PMOS barrier; and
the gate shunt makes electrical contact to the NMOS barrier and the PMOS barrier.

11. A method of forming an integrated circuit, comprising the steps of:
providing a substrate comprising semiconductor material;
forming an NMOS metal gate structure of a metal gate NMOS transistor over the semiconductor material;
forming a PMOS metal gate structure of a metal gate PMOS transistor over the semiconductor material, so that the PMOS metal gate structure abuts the NMOS metal gate structure; and
forming a gate shunt above a boundary between the NMOS metal gate structure and the PMOS metal gate structure, the gate shunt making electrical contact with the NMOS metal gate structure and the PMOS metal gate structure and providing a low resistance connection from the NMOS metal gate structure to the PMOS metal gate structure, so that the gate shunt is free of an electrical connection to other components through interconnect elements in the integrated circuit.

12. The method of claim 11, in which exactly one of the NMOS metal gate structure and the PMOS metal gate structure includes a landing area; and further comprising the step of forming an electrical connection at the landing area to other circuit elements of the integrated circuit.

13. The method of claim 11, further comprising:
forming a third metal gate structure of a third metal gate MOS transistor over the semiconductor material, the third metal gate structure including a landing area; and
forming a contact concurrently with the gate shunt, the contact making an electrical connection to the third metal gate structure at the landing area.

14. The method of claim 11, in which the step of forming the gate shunt includes:
forming a lower PMD layer over the NMOS metal gate structure and the PMOS metal gate structure;
forming a shunt hole in the lower PMD layer over boundary between the NMOS metal gate structure and the PMOS metal gate structure;
forming an adhesion layer in the shunt hole, the adhesion layer making electrical connections to the NMOS metal gate structure and the PMOS metal gate structure; and
forming a fill metal on the adhesion layer so as to fill the shunt hole.

15. The method of claim 14, in which the adhesion layer includes titanium.

16. The method of claim 14, in which the fill metal includes a metal selected from the group consisting tungsten, aluminum and cobalt aluminum alloy.

17. The method of claim 11, in which the step of forming the gate shunt includes forming a lower shunt via in a lower PMD layer and forming an upper shunt via in an upper PMD layer.

18. The method of claim 11, in which the metal gate NMOS transistor is a metal gate n-channel finFET and the metal gate PMOS transistor is a metal gate p-channel finFET.

19. The method of claim 11, in which:
the NMOS metal gate structure includes an NMOS work function layer and an NMOS fill metal;
the PMOS metal gate structure includes a PMOS work function layer and a PMOS fill metal; and
the gate shunt is formed so as to make electrical contact to the NMOS fill metal and the PMOS fill metal.

20. The method of claim 11, in which:
the NMOS metal gate structure includes an NMOS work function layer, an NMOS barrier disposed on the NMOS work function layer, and an NMOS fill metal disposed on the NMOS barrier;
the PMOS metal gate structure includes a PMOS work function layer, a PMOS barrier disposed on the PMOS work function layer, and a PMOS fill metal disposed on the PMOS barrier; and
the gate shunt is formed so as to make electrical contact to the NMOS fill metal and the PMOS fill metal.
